(19) United States
(12) Patent Application Publication
(10) Pub. No.: US 2010/0090347 A1
(43) Pub. Date: Apr. 15, 2010

(54) APPARATUS AND METHOD FOR CONTACT FORMATION IN SEMICONDUCTOR DEVICES

(76) Inventors: Stephen D. Saylor, Hamilton, MA (US); Susan Alie, Stoneham, MA (US)

Correspondence Address: PEPPER HAMILTON LLP, ONE MELLON CENTER, 50TH FLOOR, 500 GRANT STREET, PITTSBURGH, PA, 15219, US

(21) Appl. No.: 12/248,709

(22) Filed: Oct. 9, 2008

(51) Int. Cl. H01L 23/48; H01L 21/44; H01L 21/425

(52) U.S. Cl. 257/773; 438/674; 438/535; 438/597; 257/E21.476; 257/E21.473; 257/E23.01

(57) ABSTRACT

The present disclosure is directed to the preparation of a semiconductor substrate, and metallization of a contact area on the substrate to produce a contact in a semiconductor device. The method includes pre-treating the substrate by ultra fast laser treatment of a contact area, and depositing an interconnect metal layer on the contact area to create a contact. The process may include depositing a layer of dielectric-forming material on the substrate and removing a portion of the dielectric material from the substrate to reveal a contact area, prior to laser treating and metallization.

### I. TECHNICAL FIELD

The present disclosure is generally directed to the apparatus and methods to form an electrical connection in a semiconductor device and for preparing a semiconductor device for metallization to form the electrical connection.

### II. RELATED APPLICATIONS

Not applicable.

### III. BACKGROUND

Contact metallization techniques for semiconductor device manufacturing can significantly impact the price, performance and reliability of an integrated circuit. Present contact metallization techniques often include the use of precious metals such as platinum, which adds significantly to the processing cost. Known techniques typically include depositing a layer of silicon oxide, or multiple layers of silicon oxide and silicon nitride, over an active circuit element; opening a contact hole through the oxide-nitride dielectric stack down to the silicon substrate or active area (the “contact area”); depositing a thin film of platinum or other metal over the dielectric film and contact area; sintering (typically conducted at 500 to 550° C.) the metal coated wafer to form metal silicide in the contact opening, removing unreacted metal from the dielectric surface with an etchant (e.g., aqua regia); and depositing and patterning interconnect metal as needed. Other methods may include, for example, formation of titanium silicide or tungsten silicide in the contact opening.

These techniques for metallizing a contact point in a semiconductor device require the use of expensive metals (e.g., platinum or titanium), and result in waste and contamination in the process of using the metals. Also, there is a cost of time and capital equipment associated with applying these layers and removing or etching them that is undesirable. In addition, the thermal steps are expensive and time-consuming. And also, the final result is not always ideal because the bonding or adhesion between the metallized contact and the underlying active semiconductor area can be weak and have a greater-than-desired contact resistance. The resulting performance and reliability of devices made using these techniques can thus be disappointing.

Alternative methods of preparing a semiconductor substrate for metallization, and metalizing semiconductor devices are desirable to reduce semiconductor device production time and cost and to improve the reliability and performance of the same.

### IV. SUMMARY

The present disclosure provides methods for laser treatment of semiconductor devices to prepare contact points in semiconductor devices for metallization, for example for creating electrical interconnects. The present disclosure also provides articles of manufacture and devices prepared using the present methods. In some respects, the present methods and devices take advantage of the localized atomic reconfiguration or microstructuring that occurs when semiconductor materials are subjected to pulsed laser irradiation under certain conditions.

The present invention relates to methods of preparing a semiconductor device or integrated circuit prior to interconnect metallization. In an embodiment, the method relates to the preparation of a semiconductor device or integrated circuit, and metallization of a contact area on the device to produce a contact. The method comprises treating the device by irradiation with ultra fast laser treatment in the contact area, and depositing an interconnect metal layer on the contact area. The method may include laser irradiation of the contact area in the presence of a dopant, for example using short pulsed laser radiation. In some embodiments, the contact area comprises silicon. In an embodiment, the process may include depositing a layer of dielectric-forming material (for example, silicon oxide or silicon oxide and silicon nitride) on the device substrate (for example, a silicon substrate) and removing a portion of the dielectric material formed thereon from the device substrate to reveal a contact area, prior to laser treating and metallization of the contact area. According to another embodiment, the method includes preparing a semiconductor contact on a silicon substrate, comprising depositing a layer of silicon oxide (or a layer of silicon oxide and a layer of silicon nitride) over an active circuit element, forming a contact area by removing an oxide-nitride dielectric from the silicon substrate, laser irradiating the contact area in the presence or absence of a dopant, and depositing interconnect metal on the contact area to form a contact.

The device on which contacts are to be formed may be a silicon semiconductor device, or may be another material. According to various embodiments, the contact area to be treated may be silicon, germanium, gallium arsenide, indium gallium arsenide, silicon germanium, doped or undoped polysilicon, or amorphous silicon. In an embodiment, the interconnect metal may be any interconnect metal, including, for example, platinum, gold, or copper, or may be, any multilayer interconnect such as TiW—Au (titanium tungsten-gold), Ti—Pt—Au (titanium-platinum-gold), TiW—AlCu (titanium tungsten-aluminum copper), Ti—TiN—AlCu—TiW (titanium-titanium nitride-aluminum copper-titanium tungsten). In an embodiment, the laser treated contact area prior to metallization does not comprise metal The method can be performed without a sintering step. In an embodiment, the method including laser irradiation and deposition of interconnect does not form a metal silicide in the contact area.

A variety of laser irradiation conditions are possible in forming the laser-irradiated or laser-treated semiconductor material. The laser irradiating may be performed, for example, using a power range from about 150 mW to about 1 W.

In an embodiment, laser irradiation is performed in the presence of SF₆ and the contact is an N type contact. In another embodiment, the dopant is BF₃ and the contact is a P type contact.

Additional features and advantages of the invention will be made apparent from the following detailed description of illustrative embodiments that proceed with reference to the accompanying drawings.

### V. BRIEF DESCRIPTION OF THE DRAWINGS

The invention is best understood from the following detailed description when read in connection with the accompanying drawings. The following drawings illustrate simplified and exemplary embodiments and certain features of the invention, however the invention is not limited to the specific methods and instrumentalities disclosed in these drawings, in which

FIG. 1 illustrates an exemplary semiconductor device at various stages of formation of electrical (metalized) contacts therein; and

FIG. 2 illustrates steps of an exemplary method for forming (metalizing) a semiconductor device to create electrical contacts therein.

### VI. DETAILED DESCRIPTION

The present invention relates generally to methods and techniques used to prepare a semiconductor surface for metallization, processes for metalizing a semiconductor product, articles of manufacture created according to such methods and techniques, as well as to systems that perform the methods of the invention to make such articles of manufacture. Prior to metallization, a device contact region of a silicon substrate is treated by ultra-fast pulsed laser irradiation. Laser irradiation may be performed in the presence or absence of a dopant, although including a dopant produces a low resistance contact. The invention takes advantage of highly localized atomic reconfiguration or microstructuring that occurs when semiconductors are modified under femtosecond or nanosecond pulsed laser irradiation. In some contexts, such laser-treated semiconductor material has been referred to as ‘black silicon’ due to its propensity to absorb light, especially in the lower frequency ranges thereof, and its dark physical appearance.

By controlling the laser fluence, wavelength and ambient processing conditions, the contact region of a semiconductor device may be modified to allow low cost, highly reliable metallization, replacing more expensive and time consuming techniques now deployed.

A laser-processed or laser-treated semiconductor substrate generally refers to a semiconductor device substrate that has been modified by exposure to ultra-fast (or short pulsed) laser treatment. An ultra-fast pulsed laser is one capable of producing short, e.g., femtosecond, picosecond, or nanosecond length pulses. The surface of the device substrate is chemically and/or structurally altered by the laser treatment, which may, in some embodiments, result in the formation of surface features appearing as microstructures or patterned areas on the surface and/or enhanced uptake of dopants into the substrate. For example, the laser treated device substrate may include dopants that were present in a laser processing chamber during the treatment process. The device substrate may be treated in the presence of, for example, a sulfur-containing gas or solid, or in a vacuum. Methods of laser-processing a substrate are known, for example, those shown by Carey et al. in U.S. Pat. No. 7,057,256, the entirety of which is hereby incorporated by reference.

In an embodiment of the invention, photo-lithographically defined contact regions are irradiated under controlled fluence, wavelength, and ambient processing conditions to prepare the semiconductor device surface for metallization treatment. Temperature, ambient gas chemical composition, ambient gas pressure, and/or ambient gas concentration may be controlled in various embodiments of the invention. In an embodiment, a wafer is loaded into a chamber pumped down to a base pressure of 10-6 Torr, backfilled to atmosphere with a dopant gas such as SF₆, and laser treated in Si contact regions, producing an N type contact. (Alternatively, the dopant gas may be BF₃, producing a P type contact.) The dopant, when included, is selected to have a profile and topology designed to match specific electromechanical requirements of the target device which may include localized mechanical stress, bond strength, contact region doping concentration, voltage operating range, current carrying capacity, sheet resistance, junction depth, and/or operating frequency.

According to an embodiment, a method for contact formation comprises laser irradiating a contact area and depositing interconnect metal on the contact area. The laser irradiation may be performed in the presence of a dopant.

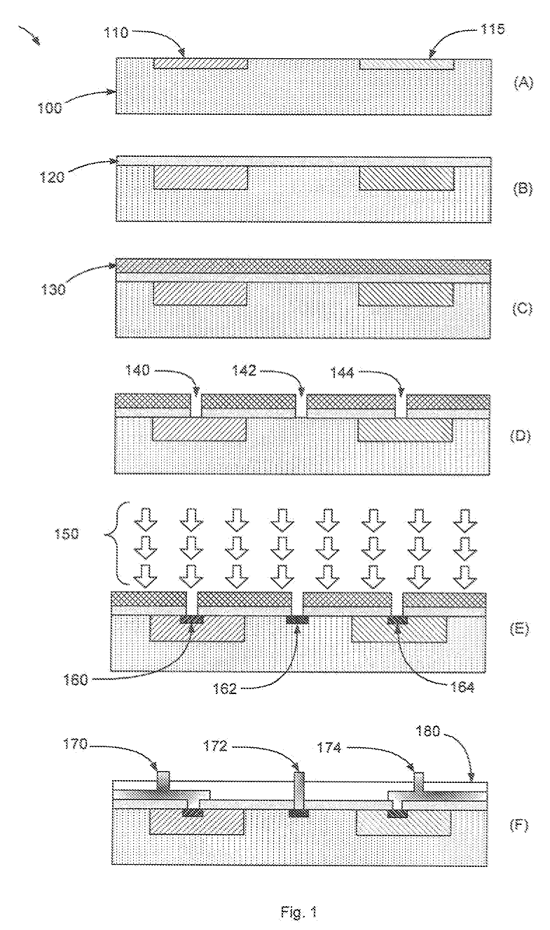

FIG. 1 illustrates an exemplary set of steps to metalize contacts on a semiconductor device 10. As shown in (A), a substrate 100 and doped elements at regions 110, 120 are provided. Any of the substrate 100 and/or the doped elements 110, 120 can be suited as active circuit elements in semiconductor device 10. Substrate 100 can also serve as a platform for making the device 10, and can be a portion of a semiconductor (e.g., silicon) wafer. Doped regions 110 and 120 can be implanted for example using ion implantation or other known techniques. In one instance, doped region 110 can be of a N type which region 120 can be of a P type. Other doping combinations, including permutations of N, P, N−, P+ and others are possible. The illustrated configuration is only exemplary, and is neither intended to be drawn to scale, nor limiting in the number and arrangement of active elements that can be employed in a semiconductor device 10 made according to the present methods.

As shown in (B), an oxide layer 120 such as silicon oxide is deposited or grown or otherwise disposed onto substrate 100 and doped regions 110 and 120. This layer 120 can also comprise a silicon nitride. Layer 120 substantially covers the active circuit elements 110, 120 and/or 100.

As shown in (C), a mask material 130 is applied to the apparatus, typically over the oxide or nitride layer 120. Mask 130 comprises for example a light-blocking mask, to shield selective areas on the surface of the semiconductor device from exposure to radiation. In some embodiments, the mask layer 130 can be a metal, ceramic, or semiconducting layer. In some embodiments, the mask layer 130 can comprise a sacrificial thin layer, as given in pending U.S. patent application Ser. No. 12/173,903, assigned to the present assignee, and which is hereby incorporated by reference. Mask layer 130 may be pre-patterned or applied to the entire surface of device 10 as appropriate.

As shown in (D), openings (holes) are cut, drilled, bored, machined, punched, etched, or otherwise made at select locations through the oxide layer 130, reaching down to the, active circuit elements below, as required by a particular device design. In the shown illustrative example, openings 140, 142, and 144 are cut to reach active elements 110, 100, and 120, respectively. These openings will allow a metal (or equivalent suitable conductive material) to be filled in to establish electrical contact with the associated active circuit elements at their connection points.

Device 10 is irradiated in (E) using short-pulsed laser or similar radiation 150 of the kind suitable for forming laser-treated effects and microstructure as described above. One or more dopants can also be introduced into or onto the device 10 as required to dope certain portions thereof. For example, a dopant can be introduced into a treatment chamber (not, shown) so that the laser treatment can enhance the take-up of said dopant specifically at exposed regions near openings 140, 142, and 144.

Radiation 150 is blocked or masked by mask layer 130 so that in general the radiation 150 does not penetrate below the mask layer 130 except for areas of mask 130 having openings 140, 142, and 144. In the exposed regions of the active elements 110, 100, and 115, the laser light 150 causes the formation of ‘black silicon’ laser-treated regions 160, 162, and 164, respectively. These laser-treated regions have advantageous properties for metallization and contact formation as will be discussed below. Once the laser-treated regions 160, 162, 164 are created, the irradiation may be stopped or suspended. Other processing steps as described in the cited references may be applied to device 10 as well as part of this step and others. The light-blocking mask layer 130 can be removed after irradiation step (E) by using mechanical or chemical means, for example by applying appropriate solvents to remove the mask layer 130. Note that application of a mask may be done in other ways or not at all if layer 120 provides sufficient masking from radiation. Also, if the applied laser light is applied locally where needed, a mask may not be required to protect other portions of device 10.

In (F), the openings 140, 142, 144 are filled with a metal or another similar conducting substance to form the electrical contacts. This metallization step establishes a low-resistance electrical contact between the metal contact posts 170, 172, and 174 and corresponding laser-treated regions 160, 162, and 164 at openings 140, 142, and 144. Note that it is not necessary to use exotic or expensive metals for this process. Other parts of a circuit can now be electrically connected to contact posts 170, 172, and 174 as desired. For example, the contact posts can be coupled to other semiconductor devices, to readouts, I/O pins, printed circuit board (PCB) connections, and so on.

In some cases, further processing steps can be performed once the contact posts 170, 172, and 174 are formed. For example, further useful layers of material 180 can be applied to some or all of the device 10 as needed for a particular design, protective coatings, insulating layers, or integrated circuit (IC) packaging can be applied.

It should be noted that in some aspects, the laser-treated regions 160, 162, 164 comprise a surface thereof proximal to the openings 140, 142, 144, which were subjected to the laser radiation 150. This surface of regions 160, 162, 164 can have a roughened, micro-spiked or similar surface texture that provides better bonding or adhesion between the metal of the contacts and the underlying regions 160, 162, 164. This improved bonding or adhesion can yield improved mechanical properties to the metalized contact points and greater reliability in the finished product. In addition, better bonding or adhesion between metal contacts points 170, 172, and 174 and corresponding laser-treated regions 160, 162, and 164 can yield improved electrical performance by lowering the contact resistance at the connection points.

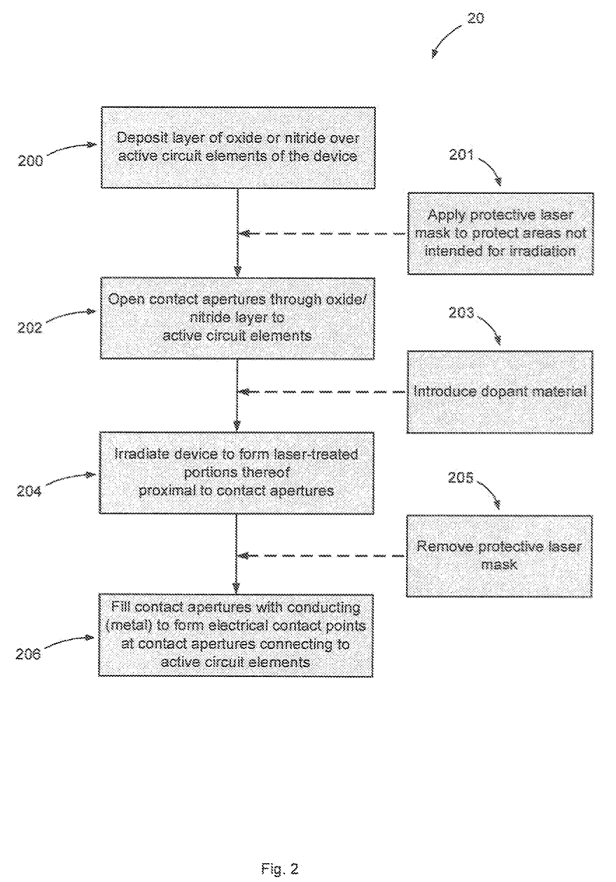

Now referring to FIG. 2, and according to some embodiments, a method 20 for contact formation in a semiconductor device includes 200 depositing a layer of silicon oxide and/or silicon nitride over active circuit elements of the device; 202 opening contact apertures through the oxide/nitride dielectric stack down to the silicon substrate or active circuit elements to create contacts areas; 204 laser irradiating the device, especially at the contact areas to create laser-treated portions in the active circuit elements proximal to the contact apertures; and 206 filling the contact apertures with a conducting material (e.g., metal) to form electrical contact points at the contact apertures connecting to the active circuit elements. The method 20 can optionally include 201 applying a protective layer or mask to protect the areas of the device not intended for irradiation; 203 introducing a dopant to enhance a characteristic of the device at or near the contact apertures; and 205 removing the protective laser mask material from the device after irradiation.

As discussed above, the laser irradiation treatment may include femtosecond laser irradiation at least at the contact areas in a dopant gas environment to yield a ‘black silicon’ or similar laser-treated portion of the active circuit elements proximal to the contact apertures. In some embodiments, this comprises laser treatment at a laser power in the range of 200-400 mW using repetitive short pulses (e.g., femtosecond duration) of radiation. Metallization of the contacts can be followed by other wafer processing steps and interconnections.

The device on which contacts are to be formed may be a silicon semiconductor device, or may be another material. The contact area to be treated may be, for example, silicon, germanium, gallium arsenide, indium gallium arsenide, silicon germanium, doped or undoped polysilicon, or amorphous silicon.

In some embodiments, the interconnect metal may include one or more of: platinum, gold, or copper, or may be any multi-layer interconnect such as TiW—Au (titanium tungsten-gold), Ti—Pt—Au (titanium-platinum-gold), TiW—AlCu (titanium tungsten-aluminum copper), Ti—TiN—AlCu—TiW (titanium-titanium nitride-aluminum copper-titanium tungsten).

In other embodiments, the laser treated contact area, prior to metallization, does not comprise a metal. That is, metallization is performed on a metal-free contact area. Laser treated contacts formed according to the methods described herein would be compatible with any standard semiconductor interconnect metallization schemes such as, for example, TiW—AlCu, Ti—TiN—Ti—Al—TiW, or Cu interconnect. Laser treated contacts would also be compatible with nonmetallic interconnect, such as doped polysilicon. The method 20 can be performed without a sintering step, permitting formation of a contact that does not comprise a metal silicide. A metal silicide contact would not typically be allowed in a polysilicon CVD tool, as it would be a contamination source.

Direct irradiation of contacts eliminates the costly use of metals such as platinum, titanium or tungsten, or others, and the capital investment in a deposition tool. It also reduces the thermal budget of the circuit process through elimination of a sinter step. In addition, the etching step is eliminated, which reduces fabrication costs and eliminates the corrosion risk introduced by aqua regia or other etchants.

The direct write laser irradiation also allows individual contacts or groups of contacts to be formed with a targeted dopant level and structuring that is different from other contacts on the same device layer. By controlling laser energy and/or ambient irradiation conditions, individual contacts may be formed to function according to distinct operating conditions. This can replace the production of multiple mask sequences used to create doped regions in semiconductor devices by ion implantation of N type or P type dopant species into photo-lithographically defined regions in silicon.

The present invention is not restricted to silicon devices. The laser doping technique could also be applied to other materials which are difficult to dope using conventional ion implantation or diffusion techniques. In embodiments, these may include InGaAs (indium gallium arsenide) or Ge (germanium) or SiGe (silicon germanium).

It will be appreciated that various of the above-disclosed apparatuses and methods, or alternatives thereof, may be desirably combined with or incorporated into other systems or applications. It will also be appreciated that various presently unforeseen or unanticipated alternatives, modifications, variations or improvements therein may be made, subsequent to the present disclosure, by those skilled in the art, any of which are intended to be encompassed by the disclosed embodiments.

Embodiments of the present invention provide several advantages over known systems. For example, elimination of a >500° C. sintering process is desirable for extending the thermal budget of a device, such as a shallow junction device or MEMS device which are mechanically sensitive to thermal cycling. In addition, the flexibility to selectively dope individual contacts to have different resistances or to dope with different materials, as is possible according to the present invention, is not viable with blanket contact processes such as platinum silicide formation. Embodiments of the present invention also permit creation of P type or N type contacts selectively at the same layer by changing the background dopant during laser treatment. Only those contacts which receive laser irradiation would incorporate dopant gas. Therefore, side-by-side contacts could be made as N type or P type by changing the backfill gas and irradiating, eliminating the need to re-pattern with separate dedicated reticles. Additionally, adhesion of the interconnect metal may be improved by embodiments of the present invention, due to the laser roughening in the contact, thereby improving device reliability through reduction of metal de-lamination or contact cracking defects, which can occur due to localized stresses induced by geometry, film stack stresses, packaging material stresses or thermal cycling.

Using laser treatment for formation of a controlled resistance contact avoids introduction of metal into the contact area, a problem that occurs with silicide formation processes. Because the laser treated contact area is metal-free, it is compatible with nonmetallic interconnect layers such as doped polysilicon. This may be advantageous to multilayer formation, and makes additional integration schemes possible. Examples include multilayer polysilicon MEMS devices and silicon CMOS image sensors. In both of these examples, the sensor elements (the MEMS or the pixels) can be formed in multilayer configurations with conductive laser treated contacts between them, followed by interconnect metallization.

The present invention should not be considered limited to the particular embodiments described above, but rather should be understood to cover all aspects of the invention as fairly set out in the attached claims. Various modifications, equivalent processes, as well as numerous structures to which the present invention may be applicable, will be readily apparent to those skilled in the art to which the present invention is directed upon review of the present disclosure. The claims are intended to cover such modifications.

We claim:

1. A method for forming electrical contacts in a semiconductor device, comprising:
forming a set of active circuit elements within a semiconductor device;
applying at least one dielectric layer onto said active circuit elements;
forming apertures in said at least one dielectric layer to expose portions of said active circuit elements;
irradiating at least said exposed portions of said active circuit elements with a pulsed source of radiation creating a textured surface on said exposed portions, said irradiation performed in a dopant environment wherein said exposed portions are doped; and
applying a conductive material within said apertures to contact said portions of said active circuit elements that were exposed to said radiation.

2. The method of claim 1, further comprising bonding said conductive material with said portions of said active circuit elements that were exposed to said radiation.

3. The method of claim 1, said irradiating comprising irradiating with a pulsed laser source.

4. The method of claim 1, said forming a set of active circuit elements comprising forming a set of doped semiconductor regions within said device to be used as active circuit elements.

5. The method of claim 1, further comprising applying a protective layer to at least some areas of said device to protect said areas from unwanted exposure to said radiation.

6. The method of claim 5, further comprising removing said protective layer following said irradiating step.

7. (canceled)

8. An article of manufacture manufactured and arranged using the following elements and process, the article comprising:
a semiconductor substrate;
at least one active circuit element disposed on or in said substrate;
a dielectric layer disposed over said semiconductor substrate and active circuit element;
an aperture within said dielectric layer providing connection access to said underlying active circuit element; and
a conductive material disposed within said aperture and providing an electrical connection to a laser-doped textured surface portion of said active circuit element, said laser-doped textured surface portion being formed by application of pulsed laser radiation in a dopant environment to said portion of said active circuit element by way of said aperture prior to disposing said conductive material within said aperture.

9. The article of claim 8, said at least one active circuit element comprising a portion of said semiconductor substrate.

10. (canceled)

11. The article of claim 8, said dielectric layer comprising an oxide layer.

12. The article of claim 8, said dielectric layer comprising a nitride layer.

13. The article of claim 8, further comprising a protective mask layer configured to protect at least some portions of said article from unwanted exposure to said laser radiation.

14. The article of claim 8, said conductive material comprising a metal.

15. The article of claim 8, said pulsed laser radiation comprising femtosecond pulsed laser radiation.
